(19) United States
(12) Patent Application Publication
(10) Pub. No.: US 2007/0285745 A1
(43) Pub. Date: Dec. 13, 2007

(54) Customizable display system

(75) Inventor: Ranjie Singh, London (CA)

Correspondence Address: ARENT FOX LLP, 1050 CONNECTICUT AVENUE, N.W., SUITE 400, WASHINGTON, DC, 20036, US

(73) Assignee: MEDICAL TECHNOLOGY (W.B.) INC.

(21) Appl. No.: 11/797,815

(22) Filed: May 8, 2007

Related U.S. Application Data
(63) Continuation-in-part of application No. 11/605,477, filed on Nov. 29, 2006.
(60) Provisional application No. 60/740,682, filed on Nov. 30, 2005.
(60) Provisional application No. 60/809,797, filed on Jun. 1, 2006.

(51) Int. Cl. G03F 1/00

(52) U.S. Cl. 358/518; 16/30

(57) ABSTRACT

A display system including a display device and an auxiliary body. The display device has a display member, such as an image affixed to at least one surface thereof. The image can be both fixed and selectively alterable. The auxiliary body is detachably secured to the display device and may include at least one of a bar code, coupon or programmable microchip. The auxiliary body is detachably secured to the display device by a scored portion, a tabbed portion or other weakened feature, so that the display device and auxiliary bodies can easily be separated.

This application is a continuation-in-part application of applicants' co-pending U.S. patent application Ser. No. 11/605,477 filed Nov. 29, 2006, entitled “CUSTOMIZABLE DISPLAY DEVICE” which claims priority to U.S. Provisional Application Ser. No. 60/740,682 entitled “CUSTOMIZABLE DISPLAY DEVICE HAVING AN ALTERABLE IMAGE” filed Nov. 30, 2005, and co-pending U.S. Provisional Application Ser. No. 60/809,797 entitled “MULTI-MEDIA DISPLAY DEVICE” filed Jun. 1, 2006. The entirety of each of these patent applications is incorporated herein by reference.

### BACKGROUND OF THE INVENTION

1. Field of the Invention

The present invention relates generally to a customizable display system including a display device having a fixed display, such as a photographic image or an altering or a moving image, and that optionally includes an auxiliary body that contains wireless media. The present invention also relates generally to a display system having a display device that may be customized with flash media as an embedded technology, in combination with an auxiliary body that contains wireless media.

2. Background of the Technology

Display devices have been used to provide fixed messages, such as for identification, security control, drinking age verification, advertising, and use as a novelty item.

However, there remains an opportunity for a display device to actively engage the user. Further, there remains an opportunity for businesses to promote a product and expand their markets, for sponsors to promote an event, and for other entities to deliver information, in a visually pleasing manner through multi-media, that also engages the user of the display device.

### SUMMARY OF THE INVENTION

The present invention is directed to a display system that includes a display device that provides fixed or alterable images or messages and at least one auxiliary body having a programmable microchip detachably secured thereto.

In an embodiment of the present invention, the display system includes a display device, such as a wristband, tag or label that may be applied on or attached to a human body, pets or property, for example the wristband tag or label has an embedded the display member.

In one variation of the display device of the display system, the image is fixed, such as a photograph or a solid color or pattern. In another variation, viewing the image embedded thereon at different angles or after performing external manipulation of the display device causes the display to appear as a moving image or an altering image. In a further variation, an alterable image may display a continuum of images for a predetermined time, such as to appear as a movie clip. Different display devices may also be joined together or otherwise coupled to form the display system of the present invention.

The display device of the display system also includes an illuminated alterable image, such as an arrangement of glowing light-emitting diodes (LEDs). The LEDs may be programmed to glow simultaneously or in an alternating manner, so as to provide the appearance of a moving image or design.

The display device of the display system may comprise a multi-media display device, including flash media features that have a liquid crystal display (LCD)-type and other types of electronic imaging receiving and/or transmitting features, allowing the device to receive wireless or otherwise transmitted images or other information. For example, images or messages, such as advertisements or announcements, may be transmitted from a remote location (e.g., from a device having a processor and transmitter receiver) for receipt by the display device. Further, for example, the display device may include electronic media, such as an automatic identification and data capture member.

Among other things, the display device of the display system may be used in advertising by a variety of businesses and industries, for example, to promote goods and services, activities, new product launches or new amusements. Multiple messages may be embedded in the image. The display device may also serve as a collectible used to commemorate events, such as sporting events, concerts, and community events.

An auxiliary body may be detachably secured to the display device. The auxiliary body may include a key fob, coupon or lanyard insert, for example. Each auxiliary body may have mounted thereon, or embedded therein a programmable microchip, bar code or other readable media for the purpose of storing information. The bar code in a coupon, for example, enables storage of information that would allow a user to benefit from discounts offered by a business entity when the bar code is scanned. The programmable microchip in the auxiliary body may store information regarding a product related to the image shown on the display device. Thus, even though the auxiliary body is separable from the display device, both portions of the display system may communicate to the user (e.g., wearer) a related message.

The display system allows the display device and auxiliary body to be initially provided in combination, but also to be detached and utilized for different uses.

Example embodiments of the present invention have now been described in accordance with the above advantages. It will be appreciated that these examples are merely illustrative of the invention. Many variations and modifications will be apparent to those skilled in the art.

### BRIEF DESCRIPTION OF THE DRAWINGS

FIGS. 1A-1D are example display devices in the form of a wristband, according to a first embodiment of the present invention;

FIGS. 2A-2B are example display device in the form of a wristband, according to a second embodiment of the present invention;

FIG. 3 is an example, flash media display device wireless transmission network of a third embodiment of the present invention;

FIGS. 4A-4B are example transmission systems according to the third embodiment of the present invention;

FIG. 5 is an example display system according to the first embodiment of the present invention;

FIG. 6 is an example display system according to the second embodiment of the present invention;

FIG. 7 is an example display system according to the third embodiment of the present invention;

FIG. 8 is an example of the sheet assembly of the first embodiment of the invention;

FIG. 9 is an example components diagram for a system, in accordance with an embodiment of the present invention; and

FIG. 10 illustrates a block diagram of various system components, in accordance with an embodiment of the present invention.

### DETAILED DESCRIPTION OF THE INVENTION

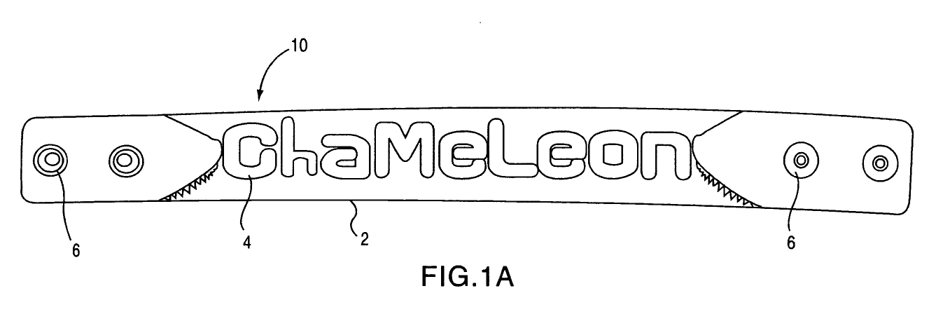

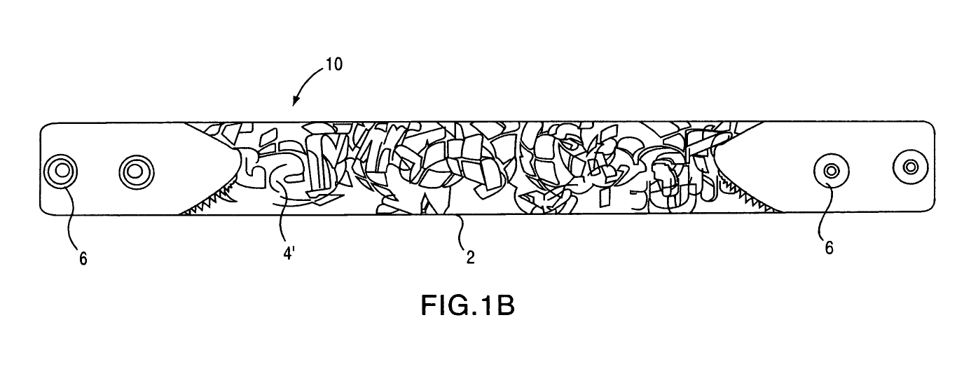

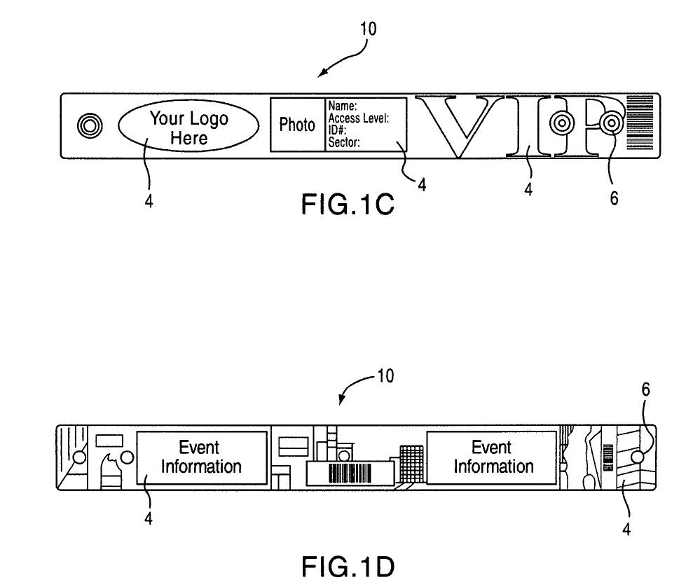

FIGS. 1A-1D illustrate an exemplary display device 10, shown as a wristband, for example, according to a first embodiment of the invention. The display device 10 may include a base member 2 embedded with a display member 4, such as a lenticular image, as shown in FIGS. 1A and 1B, which shows depth or motion as the viewing angle changes. The lenticular feature of the image optionally produces a three-dimensional effect. When changing the viewing angle of the device, for example, the device provides the appearance of a moving image. The display device 10 may be printed on both an inner or top surface and an outer or bottom surface. FIG. 1C shows, for example, a top surface of an exemplary display device, and FIG. 1D shows the bottom surface of the same device. The display device 10 may include any number of images in the display member 4, such as six or seven images, as shown in FIG. 1D.

The base member 2 of the display device 10 may be formed from any material, including, but not limited to, polyvinylchloride (PVC), vinyl/antidermatetic material, a reflective vinyl material, or other synthetic molded or extruded material. The embedded image may be formed on a material such as a polymer, using a lenticular (see, e.g., www.shortcourses.com/how/lenticular/lenticular.htm, as reviewed Nov. 29, 2005, the entire contents of which are hereby incorporated by reference). The base member 2 may be formed in any shape, so as to represent a product or commemorate an event. For example, the base member 2 may be formed in the shape of a car to represent a NASCAR® event. The display member 4 mounted to the base member 2 could also be formed to correspond to the shape and size of the base member.

The embedded image, such as the lenticular image of FIGS. 1A and 1B and the photographic images of FIGS. 1C and 1D, may be affixed to or mounted on at least one surface of the base member 2 and trimmed as necessary, such as by cutting and heat sealing (see further description of making device below). The display device 10 may also include bar coding, as shown in FIGS. 1C and 1D, to allow tracking of a large number of people or items.

The embedded image(s) may include, but are not limited to, any custom image, such as a logo, message, or approximated video footage. In one example of the first embodiment, the video footage approximation may run for a predetermined amount of time, such as 30 to 60 seconds, through use of a large number of images.

As illustrated, in FIGS. 1A-1D, the base member 2 also includes at least one fastening device 6 to secure the display device 10 to a user. The fastening device may be reusable or non-reusable. Examples of a temporary fastening device may include, for example, snaps, clips or hooks, buckles, Velcro®, a lanyard and a lanyard pouch for ease of fastening and reusability. An example of a permanent fastening device may include glue or tamperproof snap lock closures, resulting in a single fastenable use of the display device 10, wherein the fastening member 6 or device itself must be broken to remove the display device.

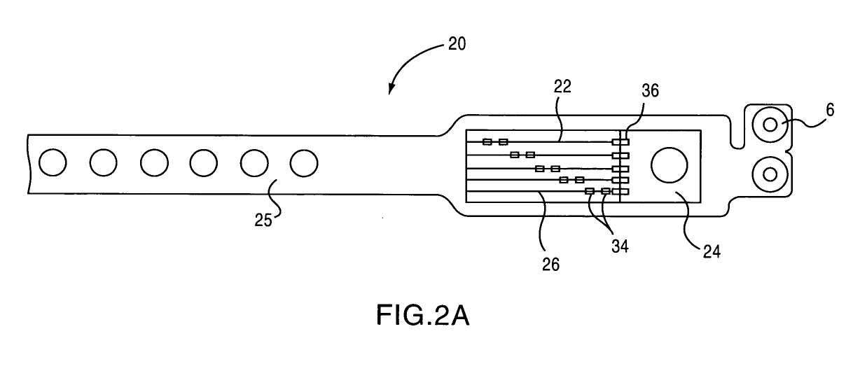

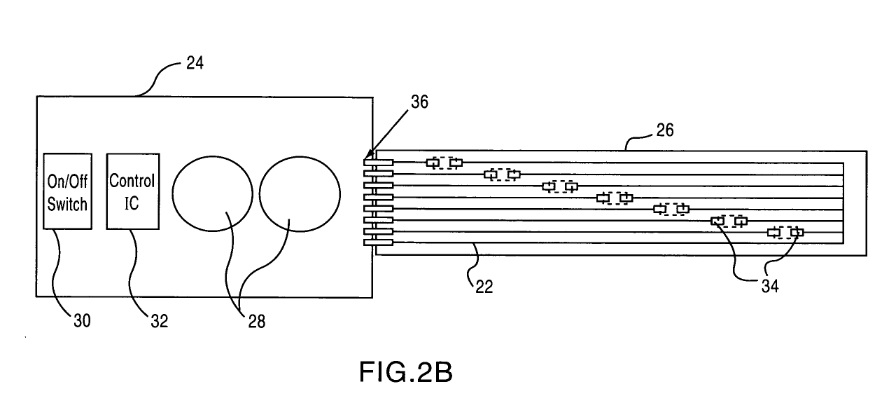

FIGS. 2A and 2B illustrate a second embodiment of the display device of the present invention. In the second embodiment, the display device 20 includes an LED circuit strip 22, having a plurality of LEDs 34, which provides the appearance of a moving image or other LED display. In one embodiment, the LED circuit strip 22 of the display device includes a first substrate 24 mounted on a second substrate 26. The first substrate 24 may be rigid and the second substrate 26 may be flexible. The first or rigid substrate 24 controls the moving image, for example, using a power source 28, such as a DC battery, and, optionally, has an ON/OFF controller 30. The display device may also include a lithium battery or other rechargeable power source in order to be re-chargeable, such as through solar or AC power sources, for example.

The rigid substrate 24 may be an organic substrate and may comprise an insulating base material or a flame resistant material, such as FR-4 or the equivalent. The rigid substrate 24 may include soldered wire or other couplings 36 to the rigid substrate 24 to the flexible substrate 26. The LEDs 34 may be mounted on the surface of the flexible substrate 26. The flexibility of the substrate allows the user to adjustably mount the display device 20 on their person or property. The flexible substrate 26 may comprise a printed circuit board (PCB) substrate of Kapton® made by the DuPont Company of Wilmington, Del. or an equivalent. In one variation, the circuit strip 22 also includes a control integrated circuit microchip, or other control device 32 to, among other things, provide timed pulses to the LEDs, for example.

The LEDs 34 on the circuit strip 22 may be a single color or multiple colors and may be formed into any suitable pattern or shape. In operation, a group of LEDs 34 may give the impression of moving light, such as a light moving back and forth, by each LED sequentially turning on and off. The LEDs 34 may also flicker, blink, or have a steady glow. The circuit strip 22 may also include, for example, polymer light-emitting diodes (PLED), light-emitting diode circuits (LEDCs), organic light-emitting diodes (OLEDs), dendrimer technology, or photovoltaic or solar cell technology for displaying an image.

In the second embodiment of the present invention, the LED circuit strip 22 may be superimposed on the lenticular image of the first embodiment, so that the display device 20 both has a moving lenticular image and a glowing LED feature.

In addition to a battery or other power source, the display device may be self-activated or powered automatically by the physical movement of the user, for example. In the display device of the present invention, for example, the display device 20, in the form of a wristband, for example, may include motion activated lighting modules, or motion generating power features, such that the LEDs 34 may glow when the user moves his or her wrist. The control of the LED operation may be made via a serial (e.g., a manually operated button or a movement activated switch) or other control device, such as a wireless communication. The display device of the second embodiment may be applied to any portion of a person's body, pets or property with an elongated portion 25, and secured with a fastening member 6.

The display device 20 may also be embedded with at least one audio chip for controlling an audio feature and flash media as discussed further below.

The display member on the surface of the display device may also be formed of a combination of the lenticular and LED circuit strip 22.

Another aspect of the second embodiment is that its display device may serve a safety function, such as by making the wearer more visible at night.

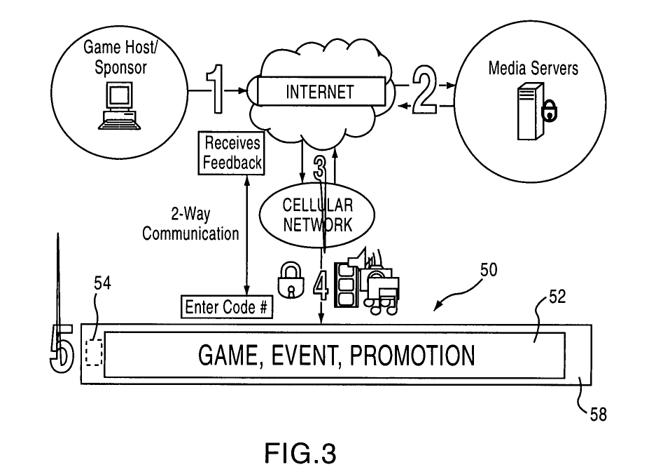

In the third embodiment of the present invention, as shown in FIG. 3, a host may transmit a wireless message to a number of display devices, such as simultaneously. For example, a sponsor of a stadium event may distribute display devices with the sponsor's trademark and/or message. At any time and from any location, the sponsor may transmit a wireless advertising message simultaneously or non-simultaneously to the distributed display devices, in the manner of a wireless handheld device or live streaming multi-media graphics video. Further, in an emergency situation, authorized first responders may transmit wireless messages, such as emergency broadcasts, to users.

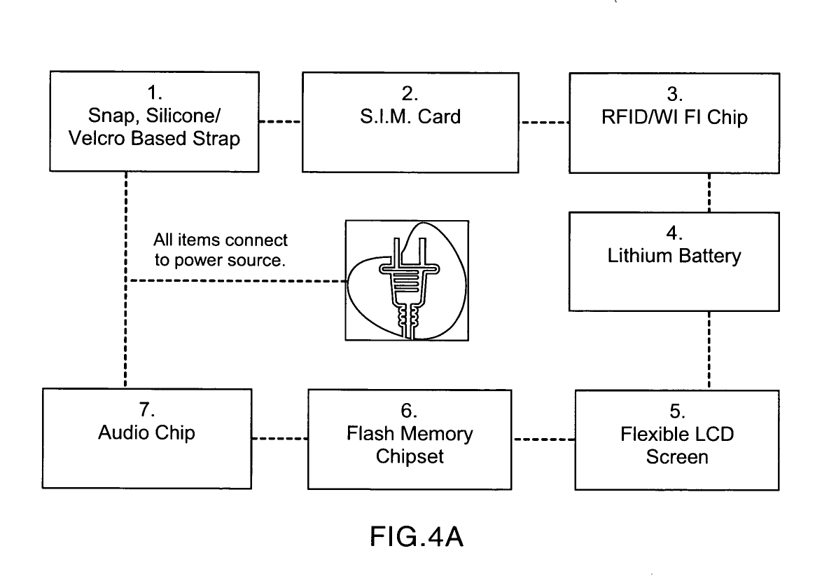

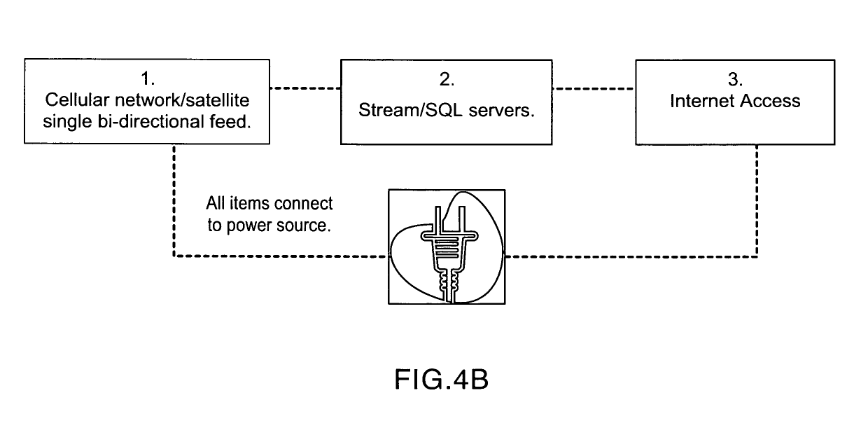

In the third embodiment of the present invention, as shown in FIG. 3 and also FIGS. 4A-4B, the display device may include such features as a flexible LCD screen 52 providing a color display for media content, and an automatic identification and data capture member 54 for receiving a wireless transmission. The automatic identification and data capture member comprises, for example, microprocessors and/or nano-integrated circuits for storage and rapid transmission of large multimedia information, such as virtual reality files. The microprocessor and nano-integrated circuits allow for webcasting and streaming of both audio and visual data.

The automatic identification and data capture member 54 may include a flash memory chipset, subscriber identity module (SIM) card, and a radio frequency identification (RFID) tag, or wireless fidelity chip for storing graphical content or other remote readable technology, The readable technology may be used, for example, for reading information from the device and for wireless transmission of information. The automatic identification and data capture member 54 may be a nano- or micro-flash memory chipset, the SIM card may be a nano- or micro-SIM card and the RFID/wireless fidelity chip may be a nano- or micro-RFID/wireless fidelity chip or other nano-electronic member. The automatic identification and data capture member 54 may also be a memory device based on complementary metal-oxide-semiconductor (CMOS) technology and having a built-in antenna, such as a “memory spot chip,” with the memory device having at least a 10 megabits-per-second data transfer rate, for example. The information in the memory device may be accessed by a read-write device incorporated into a digital device, such as a camera or cellular telephone, so as to allow rapid upload to portable media.

As shown in FIG. 3, the display device 50 may be embedded with an audio chip or sound card 56, so that an audible signal, such as a spoken message, chime other sound, may also be transmitted to and emitted by the device 50. The display device 50 may include instant messaging circuitry or other features that may receive wireless transmissions from a remote source, such as a terminal connected to the World Wide Web. The display device 50 may be formed as a console from extruded polyvinylchloride (PVC) vinyl and any other materials typically used or forming wireless handheld device housings or telephones. The display device 50 may then be mounted on a flexible member 58 that may be worn by a person or affixed to an article.

The method of transmitting a wireless message to display devices includes the user entering a designated server through a secure socket layer (SSL) via a network (e.g. Internet) connection, for example. In one embodiment, the user may design and send the media content as either a unicast or multicast stream through the network, where the streamed content is routed to a designated cellular network and multi-cast through a secure wireless application protocol and wireless fidelity combination. The unicast or multicast stream is then routed to the display devices through the cellular network. The display device then displays the unicast or multicast message.

The display device of the third embodiment may include such elements as a flexible LCD screen, a color display for media content, and/or a flash memory chipset for storing graphics. The device may be embedded with an audio chip so that an audible signal, such as a spoken message, chime other sound may also be transmitted to and emitted by the device. The display device may also include a SIM card and an RFID/wireless fidelity chip. The display device may be attached to a body or article by a fastening member, including, but not limited to, snaps, clips, hooks, buckles, Velcro®, a lanyard and a lanyard pouch.

The wireless information may be transmitted to the display device through a cellular network or a satellite single directional feed, Structured Query Language (SQL) servers and/or a network, such as the Internet, for example, as shown is FIG. 4B.

In an exemplary embodiment of the present invention, the end user may enter a predetermined number, such as a number displayed on the display device, through the display device and/or a telephone key pad and/or computer input via the host server to thereby provide information to the host server.

Applications of the multi-media display device of the present invention include secure area access entry and re-entry; patron identification; parent-child location; as a medium for receiving advertisements through the Internet; global tracking (e.g. to recover kidnapping victims); health and safety emergency notification, such as crime alert, heart attack, seizure or, accidents; for a pay-per-view band, providing continuous hourly global advertising to marketing firms, sponsors, sports teams, stadiums and events, continuous stream of global announcements and advertisements during events; issuance of emergency broadcasts; cause promotion and special interest broadcasts; educational messages transmission; political information and address transmission; and retail reciprocating promotions.

The user of the display device may enable active two-way communications with a sponsor through a network such as the Internet or through the global positioning system (GPS). The two-way communication may be achieved by entering into the device through a keyboard or other data entry member, for example, a code that allows the user to respond to a received transmission. The user may then provide feedback on a particular message, elect or vote for a particular issue or respond to the transmission, for example.

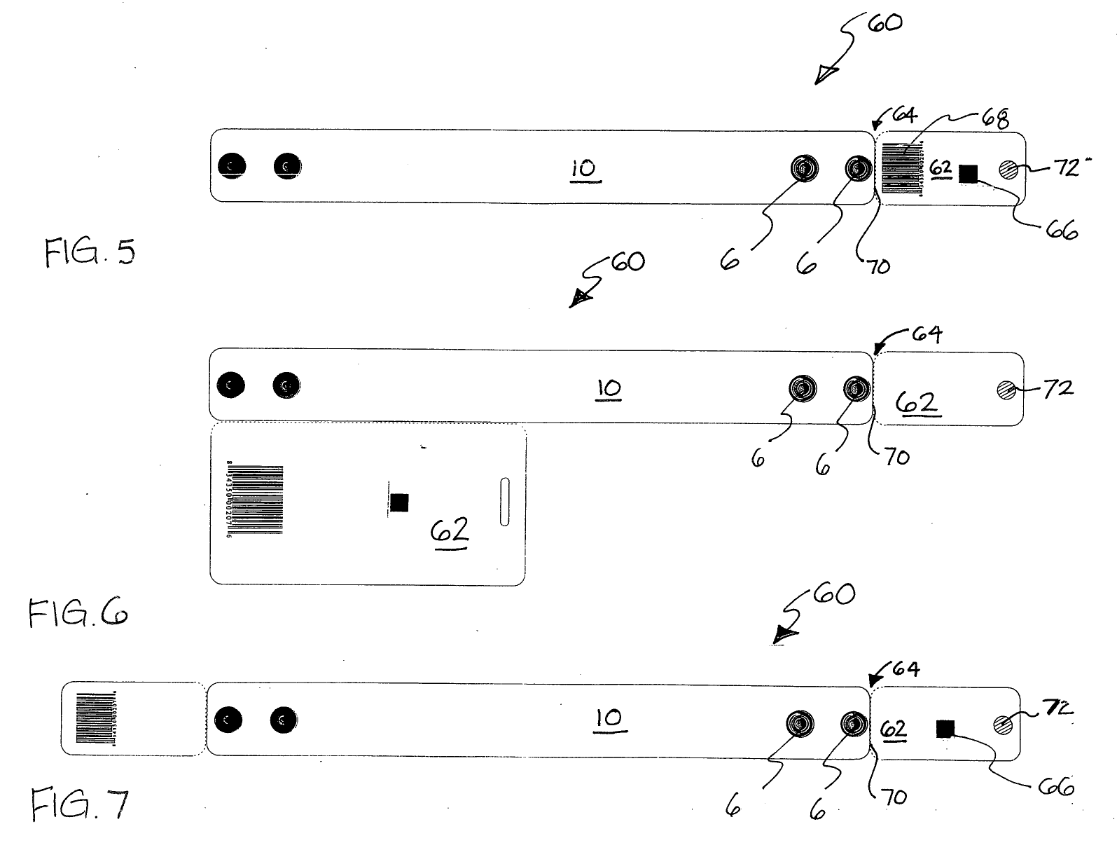

As shown in FIGS. 5-7, the display system 60 of the present invention includes a display device 10 having the display member 4 affixed to at least one surface thereof. As disclosed above, the display member 4 may include an image that is fixed or selectively alterable, such as a photographic image or a lenticular image. Alternatively, the display member may provide a multi-media display. In the display system 60 of the present invention, at least one auxiliary body 62 is detachably secured to the display device 10 by a detaching portion 64 of the display system. Thus, the auxiliary body 62 and display device 10 may be separated for different uses. For example, the display device portion 10 of the display system 60 may be a wristband that is attachable to the user's body and the auxiliary body 62 may be, but is not limited to, a key fob for hanging onto a key ring, a coupon or a lanyard insert. The fastening member 6 may be provided on each of the display device 10 and the auxiliary body 62 for these purposes.

The auxiliary body 62 may include a programmable microchip or other processing device 66 and/or a bar code 68 or other machine readable representation. The programmable processing device 66 may store information related to the image shown by the display member 4. For example, if a sponsor is advertising a product through the display member 4 of the display device 10, the microchip 66 in the auxiliary body 62 may contain information related to the advertised product.

The detaching portion 64 is disposed between the display device 10 and the auxiliary body 62 and allows the display device and auxiliary body to be easily separated. The detaching portion 64 may include, but is not limited to, a scored surface 70 as shown in FIGS. 5-7, a breakable tab, and an adhesive connection.

The fastening member 6 may include single use and reusable snaps, clips, hooks, buckles, Velcro®, apertures a lanyard and a lanyard pouch for both the display device and the auxiliary body. If the auxiliary body 62 is a key fob, for example the auxiliary body may include an aperture 72 therethrough for connecting to a key chain.

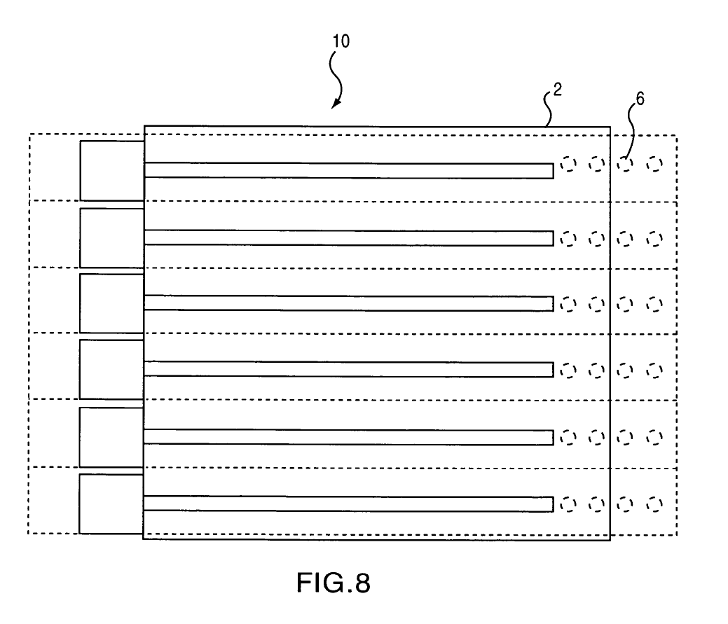

The present invention includes a method of making the display system 60. In one exemplary variation of the method, the images or display members 4 are received from, for example, event sponsors, amusement parks and/or other business entities. The images or display members include information that business entities want to promote, such as food and beverages, goods and services, activities, new product launches or new amusements. In the first stage of manufacture, the display members 4 may be mounted as lenticular images onto the base member 2 portion of the image sheet that forms the display device 10, such as a PVC vinyl/anti-dermatitic material, reflective vinyl material or other synthetic molded or extruded material. The programmable device 66 and/or bar code 68 are mounted onto the base member 2 portion of the image sheet that forms the auxiliary body 62. Image sheets containing multiple copies of a particular set of display members 4 and auxiliary bodies are produced as shown in FIG. 8. The detaching portion 64 may then be formed between the display device portion 10 and the auxiliary body portion 62 to define the display device and the auxiliary body. The detaching portion 64 may include a “weakness feature”, such as a scored portion, to ease detachment. The detaching portion 64 may also include a tabbed portion that is easily breakable so as to leave clean edges without perforations on the display device 10 and auxiliary body 62.

In the second stage of manufacture, the image sheets are run through a high-precision, high-frequency machine that die cuts the image sheets into separate display systems, sandwiches the display members 4 and programmable microchips to the base member 2 material and heat seals the two sections together in a manner that eliminates sharp edges. In addition, heat sealing prevents water and moisture from entering the space between the base member 2 and the embedded image of the display member 4 and between the base member 2 and a laminate covering the programmable microchip 66 and bar coding 68 of the auxiliary body. Thus, the display device 10 and auxiliary body 62 may be waterproof and/or moisture proof or repellent. Further, the polymeric material containing the embedded image of the display member 4, may be water repellent, so that the embedded image is not altered by water or moisture. As a result, the display device 10 and auxiliary body 62 may be worn or used at outdoor events, regardless of the weather.

In the third stage of manufacture, after the display device 10 and auxiliary body 62 are heat sealed, the display device and auxiliary body are transferred to a station where fastening devices 6 are added thereto, so that the display device and auxiliary body may be attached to articles. Once the sheet is cooled, the display device 10 may be easily separated from the auxiliary body along the detaching portion 64.

In another embodiment of the method of making the display device, the display member 4 and programmable microchip 66 may be laminated to the base member 2. The affixed display member 4 and programmable microchip 66 laminated to the base member 2 may then be die cut from the image sheet shown, into individual display systems 60, without heat sealing.

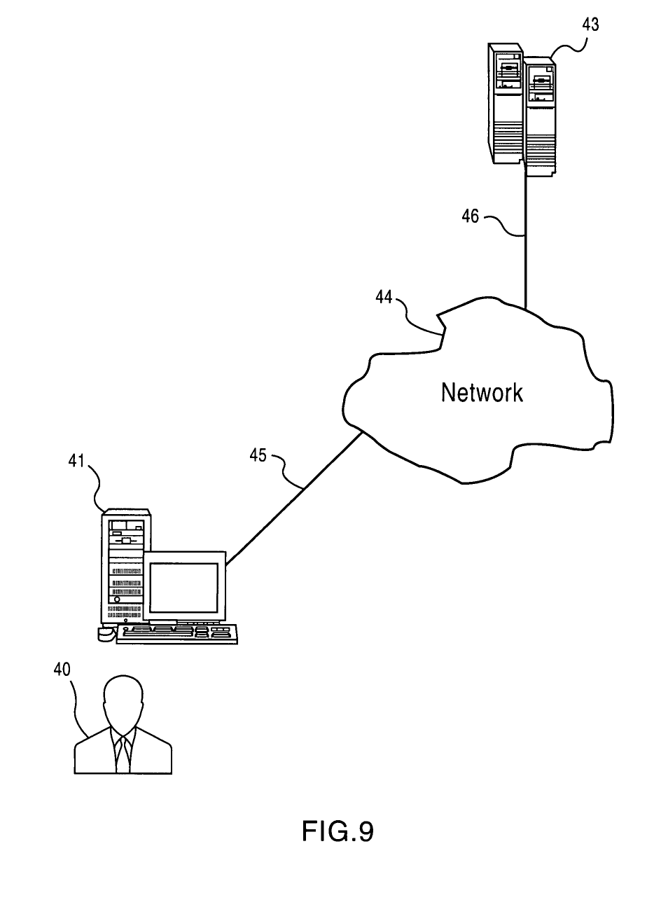

Access to the database and capabilities of the system of an embodiment of the present invention occur via hardware and access selections. As shown in FIG. 9, in an embodiment of the present invention, with one option, a user 40, for example, a host, can use locally loaded software at the user's terminal 41, such as a personal computer (PC), minicomputer, microcomputer, mainframe computer, telephone device, hand-held device such as a personal digital assistant (PDA), or other wireless device with a processor, display, and capability of connecting to a network 44, such as the Internet. The user 40 can use the terminal to access a server 43 via couplings 45, 46. The server 43 includes, for example, a PC, minicomputer, microcomputer, mainframe computer, or other device having a processor and a repository for data or connection to a repository for data. The couplings 45, 46 include, for example, wired, wireless, or fiberoptic connections. In another embodiment, the method and system of the present invention operate in a stand-alone environment, such as on a single terminal.

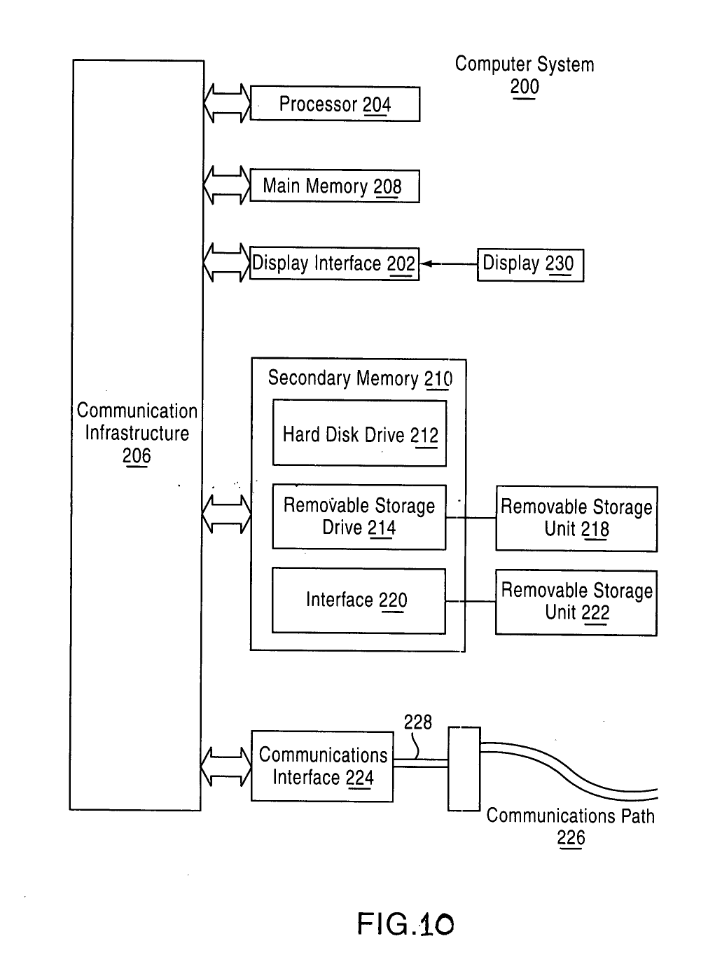

The present invention may be implemented using hardware, software or a combination thereof and may be implemented in one or more computer systems or other processing systems. In one embodiment, the invention is directed toward one or more computer systems capable of carrying out the functionality described herein. An example of such a computer system 200 is shown in FIG. 10.

Computer system 200 includes one or more processors, such as processor 204. The processor 204 is connected to a communication infrastructure 206 (e.g., a communications bus, cross-over bar, or network). Various software embodiments are described in terms of this exemplary computer system. After reading this description, it will become apparent to a person skilled in the relevant art(s) how to implement the invention using other computer systems and/or architectures.

Computer system 200 can include a display interface 202 that forwards graphics, text, and other data from the communication infrastructure 206 (or from a frame buffer not shown) for display on the display unit 230. Computer system 200 also includes a main memory 208, preferably random access memory (RAM), and may also include a secondary memory 210. The secondary memory 210 may include, for example, a hard disk drive 212 and/or a removable storage drive 214, representing a floppy disk drive, a magnetic tape drive, an optical disk drive, etc. The removable storage drive 214 reads from and/or writes to a removable storage unit 218 in a well-known manner. Removable storage unit 218, represents a floppy disk, magnetic tape, optical disk, etc., which is read by and written to removable storage drive 214. As will be appreciated, the removable storage unit 218 includes a computer usable storage medium having stored therein computer software and/or data.

In alternative embodiments, secondary memory 210 may include other similar devices for allowing computer programs or other instructions to be loaded into computer system 200. Such devices may include, for example, a removable storage unit 222 and an interface 220. Examples of such may include a program cartridge and cartridge interface (such as that found in video game devices), a removable memory chip (such as an erasable programmable read only memory (EPROM), or programmable read only memory (PROM)) and associated socket, and other removable storage units 222 and interfaces 220, which allow software and data to be transferred from the removable storage unit 222 to computer system 200.

Computer system 200 may also include a communications interface 224. Communications interface 224 allows software and data to be transferred between computer system 200 and external devices. Examples of communications interface 224 may include a modem, a network interface (such as an Ethernet card), a communications port, a Personal Computer Memory Card International Association (PCMCIA) slot and card, etc. Software and data transferred through communications interface 224 are in the form of signals 228, which may be electronic, electromagnetic, optical or other signals capable of being received by communications interface 224. These signals 228 are provided to communications interface 224 through a communications path (e.g., channel) 226. This path 226 carries signals 228 and may be implemented using wire or cable, fiber optics, a telephone line, a cellular link, a radio frequency (RF) link and/or other communications channels. In this document, the terms “computer program medium” and “computer usable medium” are used to refer generally to media such as a removable storage drive 214, a hard disk installed in hard disk drive 212, and signals 228. These computer program products provide software to the computer system 200. The invention is directed to such computer program products.

Computer programs (also referred to as computer control logic) are stored in main memory 208 and/or secondary memory 210. Computer programs may also be received through communications interface 224. Such computer programs, when executed, enable the computer system 200 to perform the features of the present invention, as discussed herein. In particular, the computer programs, when executed, enable the processor 204 to perform the features of the present invention. Accordingly, such computer programs represent controllers of the computer system 200.

In an embodiment where the invention is implemented using software, the software may be stored in a computer program product and loaded into computer system 200 using removable storage drive 214, hard drive 212, or communications interface 224. The control logic (software), when executed by the processor 204, causes the processor 204 to perform the functions of the invention as described herein. In another embodiment, the invention is implemented primarily in hardware using, for example, hardware components, such as application specific integrated circuits (ASICs). Implementation of the hardware state machine so as to perform the functions described herein will be apparent to persons skilled in the relevant art(s).

In yet another embodiment, the invention is implemented using a combination of both hardware and software.

Although the invention has been described based upon these preferred embodiments, it would be apparent to those skilled in the art that certain modifications, variations, and alternative constructions would be apparent, while remaining within the spirit and scope of the invention. In order to determine the metes and bounds of the invention, therefore, reference should be made to the appended claims.

What is claimed is:

1. A display system comprising:
a display device having a display member affixed to at least one surface thereof, the display member including an image that is selectively alterable;
at least one auxiliary body detachably secured to the display device by a detaching portion; and
a fastening member on the display device and each of the at least one auxiliary body for securing the display device and auxiliary body to articles.

2. The display system according to claim 1, wherein the at least one auxiliary body comprises at least one of a programmable microchip and a bar code.

3. The display system according to claim 1, wherein the at least one auxiliary body is selected from a group comprising a coupon, a key fob and a lanyard insert.

4. The display system according to claim 1, wherein the at least one auxiliary body comprises a programmable device that stores information related to the image shown by the display member.

5. The display system according to claim 1, wherein the detaching portion comprises a weakness feature located between the display device and the at least one auxiliary body.

6. The display system according to claim 5, wherein the weakness feature comprises a scored surface.

7. The display system according to claim 1, wherein the detaching portion comprises a breakable tab located between the display device and the at least one auxiliary body.

8. The display system according to claim 1, wherein the detaching portion comprises an adhesive connection between the display device and the at least one auxiliary body.

9. The display system according to claim 1, wherein the display device is a wristband and the auxiliary body is a key fob.

10. The display system according to claim 1, wherein the display member comprises at least one of a lenticular and a photographic image.

11. The display system according to claim 1, wherein the fastening member is a single use snap.

12. The display system according to claim 1, wherein the fastening member is a reusable snap.

13. The display system according to claim 1, wherein the display device further comprises electronic media.

14. The display system according to claim 13, wherein the electronic media comprises an automatic identification and data capture member.

15. The display system according to claim 14, wherein the automatic identification and data capture member comprises a memory spot chip.

16. A method of making a display system comprising a display device and an auxiliary body, the method comprising:
affixing a display member onto a display device portion of an image sheet;
mounting a programmable device onto an auxiliary body portion of the image sheet;
forming a detaching portion between the display device portion and the auxiliary body portion;
heat sealing the display member and programmable microchip to the display device portion and auxiliary body portion, respectively of the display system to form adjoining edges for the display device and auxiliary body; and
cooling the sheet.

17. The method according to claim 16, wherein forming the detaching portion comprises:
forming a weakness feature between the display device and the auxiliary body portion.

18. The method according to claim 16, wherein forming the line of weakness comprises:
forming scoring on the image sheet between the display device and the auxiliary body portion.

19. The method according to claim 16, wherein forming the weakness feature comprises:
forming a tabbed portion between the display device and the auxiliary body portion.

20. The method according to claim 16, further comprising:
affixing electronic media onto the display device portion of the image sheet.

21. The method according to claim 20, wherein affixing electronic media onto the display device portion of the image sheet comprises:
affixing an automatic identification and data capture member.

22. The method according to claim 21, wherein affixing the automatic identification and data capture member comprises:
affixing a memory spot chip onto the display device portion of an image sheet.

23. A display system, comprising:
display means for displaying an image that is both fixed and selectively alterable, the display means being affixed to at least one surface of a display device;
at least one auxiliary body detachably secured to the display device by detaching means, the at least one auxiliary body comprising a programmable microchip; and
fastening means for securing the display device and at least one auxiliary body to articles.

24. The display system according to claim 23, wherein the display means comprises a wristband with a lenticular image and the at least one auxiliary body comprises a key fob.
